(19) United States
(12) Patent Application Publication
(10) Pub. No.: US 2014/0264269 A1
(43) Pub. Date: Sep. 18, 2014

(54) TUNABLE LIGHT EMITTING DIODE USING GRAPHENE CONJUGATED METAL OXIDE SEMICONDUCTOR-GRAPHENE CORE-SHELL QUANTUM DOTS AND ITS FABRICATION PROCESS THEREOF

(71) Applicant: KOREA INSTITUTE OF SCIENCE AND TECHNOLOGY, Seoul (KR)

(72) Inventors: Won-Kook Choi, Seoul (KR); Dong Ick Son, Seoul (KR); Byoung Wook Kwon, Seoul (KR); Dong Hee Park, Seoul (KR)

(73) Assignee: KOREA INSTITUTE OF SCIENCE AND TECHNOLOGY, Seoul (KR)

(21) Appl. No.: 14/355,399

(22) PCT Filed: Oct. 5, 2012
(86) PCT No.: PCT/KR2012/008096

§ 371 Date: Apr. 30, 2014

(30) Foreign Application Priority Data
Nov. 1, 2011 (KR) 10-2011-0112972

(51) Int. Cl. H01L 33/06; H01L 33/26; H01L 33/00

(52) U.S. Cl. CPC H01L 33/06; H01L 33/005; H01L 33/26
USPC 257/13; 438/47

(57) ABSTRACT

Disclosed is a method of preparing metal oxide semiconductor-graphene core-shell quantum dots by chemically linking graphenes with superior electrical properties to a metal oxide semiconductor, and a method of fabricating a light emitting diode by using the same. The light emitting diode according to the present invention has the advantages that it shows excellent power conversion efficiency, the cost for materials and equipments required for its fabrication can be reduced, its fabricating process is simple, and it is possible to mass-produce and enlarge the size of display based on a quantum dot light emitting diode. Further, the present invention relates to core-shell quantum dots that can be used in fabricating a light emitting diode with a different wavelength by using various multi-component metal oxide semiconductors and a fabricating method thereof.

### TECHNICAL FIELD

The present invention relates to a method of preparing metal oxide semiconductor-graphene core-shell quantum dots by chemically linking graphenes with superior electrical properties to a metal oxide semiconductor, and a method of fabricating a light emitting diode by using the same. The light emitting diode according to the present invention has the advantages that it shows excellent power conversion efficiency, the cost for materials and equipments required for its fabrication can be reduced, its fabricating process is simple, and it is possible to mass-produce and enlarge the size of display based on quantum dot-light emitting diode. Further, the present invention relates to core-shell quantum dots that can be used in fabricating a light emitting diode with a different wavelength by using various multi-component metal oxide semiconductors and a fabricating method thereof.

### BACKGROUND ART

Conventionally, the synthesis of quantum dots (QD) has been carried out by using a pyrolysis method, and researches on the fabrication of stable core/shell quantum dots with high efficiency and application thereof have been actively performed based thereon. Meanwhile, for the application to LED, an individual particle with high light emitting efficiency should be effectively arranged. For this, conductive and electrolyte polymers have been widely used as a carrier. Dabbousi et al. investigated LED properties of CdSe nanocrystallites (quantum dots) that are incorporated into thin films of polyvinylcarbazole and an oxadiazole derivative and sandwiched between ITO and Al electrodes. It was found that the wavelength of light emitted therefrom was regulated depending on the size and power conversion efficiency of quantum dots was increased in proportion to low temperature [B. O. Dabbousi et al., Appl. Phys. Lett., 66, 1316 (1995)]. As an extension of such studies, CdSe/ZnS core/shell type quantum dots were combined with poly(phenylene vinylene) and their LED properties were analyzed under an inert N₂ atmosphere. A single layer of quantum dots can be protected by an organic surfactant, but it is possible to protect simultaneously cationic and anionic surfaces. When these surfaces are subjected to “capping” with other types of semiconductor, since both the cationic and anionic surfaces can be protected, it is possible to obtain very stable quantum dots. Further, if the core/shell is formed by combining with several types of semiconductor, it is possible to easily regulate a band gap size [S. Kim et al., J. Am. Chem. Soc., 125, 11466 (2003)].

As a prior art relating to quantum dots, Korean Patent Application Publication No. 2011-0072210 describes a backlight device having superior color reproduction such as blue, green and red which comprises a plurality of light sources arranged at regular intervals and a diffusion sheet diffusing light emitted from the light source, wherein the diffusion sheet includes quantum dots capable of selectively changing the wavelength band of light. However, since CdSe is one of six substances banned by the Restriction on Hazardous Substances (RoHS) directive and classified into a hazardous substance for utilization and commercialization as well as for use in life, it was reported that the use of CdSe is not suitable to fabricate a photoelectronic device.

In addition, Korean Patent No. 10-0783251 discloses a multi-layered white light emitting diode comprising an UV light emitting diode; a mixed fluorescent layer comprising a green fluorescent and a blue fluorescent that are formed on the upper surface of the UV light emitting diode; and a red-light emitting quantum dot layer which is formed on the upper surface of the mixed fluorescent layer. However, this light emitting diode has a problem in that quantum dot light emitting materials are too expensive and its brightness is poor.

Therefore, in case of red and green quantum dots, light emitting efficiency thereof is good, but in order to fabricate a white LED using quantum dots, there is a need to develop a method of fabricating quantum dots having improved blue light emitting efficiency. Hitherto, CdSe/ZnS core-shell (Adv. Mater. 2006, 18, 2545-2548) and ZnCdS alloy (Nano Lett., 2007, Vol.7, No.8) have been studied as a material for blue quantum dots, but all these materials include Cd, and thus there is a need to develop quantum dots and a light emitting diode using the same to compensate for this drawback.

### SUMMARY OF INVENTION

### Technical Problem

In order to overcome these problems, the present inventors have endeavored to study and found the fact that if metal oxide semiconductor-graphene core-shell quantum dots are formed to have a structure in which the surface of a metal oxide semiconductor is covered with graphene through the chemical binding between the metal oxide semi-conductor material and graphene with high electroconductivity is formed, these quantum dots convert into zero-dimensional quantum dots, and it is possible to obtain blue light emitting quantum dots through band gap regulation.

### Solution to Problem

It is an object of the present invention to provide metal oxide semiconductor-graphene core-shell quantum dots.

It is another object of the present invention to provide a light emitting diode using the metal oxide semiconductor-graphene core-shell quantum dots.

In accordance with the aspect thereof, the present invention provides a metal oxide semiconductor-graphene core-shell quantum dot having a structure in which a metal oxide semiconductor nanoparticle is a core and said core is covered with graphene in a shell shape.

Further, the present invention provides a light emitting diode which is characterized in that it includes a metal oxide semiconductor-graphene core-shell quantum dot as a single active layer and is a white light emitting diode, wherein the metal oxide semi-conductor-graphene core-shell quantum dot has a structure in which a metal oxide semiconductor nanoparticle is a core and said core is covered with graphene in a shell shape.

In addition, the present invention provides a method of fabricating a light emitting diode, comprising:

preparing a solution by adding the metal oxide semiconductor-graphene quantum dot to alcohol;

forming a first conductive polymer layer by coating a hydrophilic polymer on a transparent electrode substrate;

forming a second conductive polymer layer by coating a hydrophobic polymer on the first conductive polymer layer;

forming a single active layer by coating the alcohol solution of the metal oxide semi-conductor-graphene quantum dot on the second conductive polymer layer;

forming a supplementary layer on the single active layer; and

forming a metal electrode layer.

### Advantageous Effects of Invention

The metal oxide semiconductor-graphene core-shell type particles of the present invention exhibit excellent electron mobility, and thereby, it is possible to significantly increase their power conversion efficiency as compared with conventional metal oxides.

Further, in the case that a light emitting diode is fabricated by using the metal oxide semiconductor-graphene core-shell quantum dots, the cost for materials and equipments required for the fabrication can be reduced, its fabricating process is simple, and it is possible to mass-produce and enlarge the size of display based on quantum dot-light emitting diode.

In addition, it is possible to select a variety of multi-component metal oxide semi-conductors, and when graphene is chemically linked thereto, it is easy to regulate their corresponding band gap, which makes possible to fabricate a light emitting diode having a different wavelength.

### BRIEF DESCRIPTION OF DRAWINGS

FIG. 1 is a schematic diagram of synthesizing the zinc oxide-graphene core-shell shaped quantum dots prepared in Example 1.

FIG. 2a is a TEM (transmission electron microscope) photograph of nano-sized powder that is prepared by removing a zinc oxide core from the zinc oxide-graphene quantum dots prepared in Example 1 and extracting pure graphene therefrom.

FIG. 2b is X-ray diffraction patterns of the zinc oxide-graphene quantum dots and graphene prepared in Example 1, showing that zinc oxide quantum dot cores grown in the directions of (100), (002) and (101) are formed and graphene is formed in the directions of (002) and (100).

FIG. 3 is a photoluminescence spectrum of zinc oxide semiconductor core-shell quantum dots that are chemically linked to graphene in the quantum dots prepared in Example 1.

FIG. 4 is a schematic diagram of a polymer hybrid light emitting diode comprising the zinc oxide-graphene quantum dots prepared in Example 1.

FIG. 5 is a schematic energy band diagram of the light emitting diode fabricated in Example 2.

FIG. 6 is a current density-voltage (J-V) characteristic curve observed for the polymer hybrid light emitting diode fabricated in Example 2.

FIG. 7 is an electroluminescence (EL) spectrum of the polymer hybrid light emitting diode fabricated in Example 2.

FIG. 8 is schematic diagrams of PL and EL properties.

FIG. 9 represents the relationship of a light emitting energy level to multi-component oxide semiconductor materials in which valence band energy levels of semiconductor nanoparticles, that are chemically linked to the graphene used in implementing red (610-630 nm (1.96-2.03 eV)), green (520-540 nm (2.29-2.38 eV)) and blue (440-460 nm (2.69-2.81 eV)) among electroluminescence, are in the range of 6.30-6.45 eV (red), 6.65-6.80 eV (green), and 7.00 7.25 eV (blue), respectively.

### BEST MODE FOR CARRYING OUT THE INVENTION

Hereinafter, the present invention will be described in more detail.

In accordance with an aspect, the present invention is characterized by metal oxide semiconductor-graphene core-shell quantum dots having a structure in which a metal oxide semiconductor nanoparticle is a core and said core is covered with graphene in a shell shape.

In case of the metal oxide semiconductor forming a core in the present invention, metal oxides whose light band gap capable of absorbing UV is 3.0 eV or higher can be used, and examples thereof may include TiO₂, Nb—TiO₂, Sb—TiO₂, SnO₂, ZnO, In₂O₃, CuO, MgZnO, MgO, In₁₋ₓ(SnO₂)ₓ (0<x<0.15, ITO), Ga₂O₃ and BeO, F—SnO₂, and preferably zinc oxide (ZnO).

The graphene used as a shell for covering such a metal oxide semiconductor is preferably a graphene sheet composed of a single layer or several layers. Further, the graphene has superior heat conductivity, electron mobility and flexibility, and can assume a curved form with a curvature so as to be chemically linked along to the core surface of the metal oxide semiconductor in several nanometers. Since stress is applied thereto due to such a curved form, the graphene can be used as a semiconductor having a band gap which corresponds to the midinfrared range depending on the magnitude of the applied stress.

According to the present invention, the metal oxide semiconductor nanoparticle forming a core and graphene forming a shell have a structure where they are linked through the chemical bonding with oxygen atoms.

In order to form a structure for maximizing electron mobility by using a conventionally used metal oxide semiconductor as a core of quantum dots and efficiently inducing the binding of graphene with good electroconductivity thereto, the present invention provides a metal oxide semiconductor-graphene core-shell quantum dot structure in which the surface of the metal oxide semiconductor is covered with graphene. Here, it is possible to easily regulate a center of luminescence of the metal oxide semiconductor-graphene core-shell quantum dot by appropriately selecting a metal oxide semiconductor material having various types of band gap. Further, the metal oxide semiconductor-graphene core-shell quantum dot has an advantage of being efficiently operated over that using a conventional metal oxide semiconductor.

In the metal oxide semiconductor-graphene of the present invention, it is preferred that electroluminescence of an active layer is generated in the range of visible light, and red, green and blue light emitting semiconductor nanoparticles are mixed. In case of a conventional metal oxide semiconductor not being linked to graphene, it shows light emitting properties corresponding to the energy difference between a conduction band (CB) and a valence band (VB) which is called a band gap. However, in the metal oxide semiconductor-graphene core-shell quantum dots, light emitting corresponding to the energy difference between the lowest unoccupied molecular orbital (LUMO) energy level of graphene and the VB energy level of the metal oxide semiconductor is observed. At this time, the conduction band (CB) energy level of the metal oxide semi-conductor nanoparticles that are chemically linked to graphene so as to implement red (610-630 nm (1.96-2.03 eV)), green (520-540 nm (2.29-2.38 eV)), and blue (440-460 nm (2.69-2.81 eV)) among electroluminescence lights should be higher than the Fermi energy (4.4eV) of graphene. If it is lower than 4.4 eV, there is a problem in that electrons introduced from a cathode are directly transported to the conduction band of the metal oxide semiconductor, and thereby, it is only possible to show electroluminescence corresponding to the band gap of the metal oxide semiconductor, leading to the loss of graphene effect. Further, it is possible to use a multi-component metal oxide semiconductor whose valence band (VB) energy level is in the range of 6.30-6.45 eV (red), 6.65-6.80 eV (green), and 7.00 7.25 eV (blue), respectively.

Thus prepared quantum dots have an average diameter of 5-30 nm, preferably about 10 nm.

Meanwhile, the present invention provides a light emitting diode which is characterized in that it includes the thus prepared metal oxide semiconductor-graphene core-shell quantum dots as a single active layer and is a white light emitting diode.

As a new method for regulating a band gap, but not though the regulation of nanoparticle size or impurity doping, in case of using a center of luminescence corresponding to the band gap of the conventional metal oxide semiconductor nanoparticle as an active layer, it is possible to fabricate a new type of an electroluminescence diode in which graphene is linked to the metal oxide semiconductor having various band gaps, and to implement blue light emitting by regulating the center of luminescence.

Further, the method of fabricating a light emitting diode using the new type of quantum dots according to the present invention comprises:

preparing a solution by adding the metal oxide semiconductor-graphene quantum dots to alcohol;

forming a first conductive polymer layer by coating a hydrophilic polymer on a transparent electrode substrate;

forming a second conductive polymer layer by coating a hydrophobic polymer on the first conductive polymer layer;

forming a single active layer by coating the alcohol solution of the metal oxide semi-conductor-graphene quantum dots on the second conductive polymer layer;

forming a supplementary layer on the single active layer; and

forming a metal electrode layer.

The preferred method of fabricating a light emitting diode according to the present invention can be exemplified as follows.

In the fabrication method of the present invention, the step of preparing a quantum dot alcohol solution can be carried out, for example, by dispersing oxidized graphite in a solvent, and mixing with a precursor of a metal oxide semiconductor, to thereby prepare metal oxide semiconductor-graphene quantum dot powder, followed by dissolving the same in alcohol such as ethanol.

The step of forming a first conductive polymer layer can be performed by depositing a coating of a hydrophilic polymer on a transparent electrode substrate such as glass and polymer substrate and drying the same. The hydrophilic polymer suitable for this step can be selected from the group consisting of polyacetylene (PAC), poly(p-phenylene vinylene) (PPV), polypyrrole (PPY), polyaniline (PANI), polythiophene (PT), and poly(3,4-ethylenedioxythiophene)poly(styrenesulfonate) (PEDOT:PSS). Such a first conductive polymer layer is applied to the substrate so as to lower an energy barrier between the transparent electrode and the hydrophilic polymer and to increase mobility of holes in which a UV absorbing layer is generated.

Next, the step of forming a second conductive polymer layer can be conducted by spray-coating a hydrophobic polymer on the first conductive polymer layer and hardening the same. The hydrophobic polymer suitable for this step can be selected from the group consisting of CBP (4,4′-Bis(N-carbazolyl)-1,1′-bipheny) 1,4-bis(diphenylamino) benzene, TPB (Tetra-N-phenylbenzidine), NPD (N,N′-di-[(1-naphthyl)-N,N′-diphenyl]-1,1′-biphenyl)-4,4′-diamine), and TPD (N,N′-bis(3-methylphenyl)-N,N′-diphenylbenzidine). In order to increase hole mobility generated due to the presence of holes between energy levels of the light absorbing layer and the first conductive polymer layer, the HOMO (highest occupied molecular orbital) energy level of such a second conductive polymer layer is applied onto the first conductive polymer layer.

The substrate on which the second conductive polymer layer is formed is coated with the metal oxide semiconductor-graphene quantum dot solution prepared above, to thereby form a single active layer.

In order to facilitate rapid transport of electrons generated at the light absorbing layer, a supplementary layer for reducing a work function is formed on the single active layer. Here, as a material suitable for the supplementary layer, alkali compounds such as LiF and Cs₂CO₃ can be used, and it is preferable to use cesium carbonate.

A conventional metal electrode layer is then formed on the supplementary layer. At this time, Ag, Al and the like can be used as a metal electrode, and it is preferable to use a low-priced Al electrode. When the metal electrode layer is formed, the fabrication of a light emitting diode is completed.

As such, since the quasi-metal oxide semiconductor-graphene core-shell shaped particles used as a light absorbing layer according to the present invention are covered with graphene having very high electron mobility, they show very high electron transfer rate and superior light properties, and thereby, it is possible to more efficiently fabricate a light emitting diode as compared with conventional metal oxides.

Further, it is possible to select a variety of multi-component metal oxide semi-conductors such as mono-, di-, tri-, tetra-, penta- and hexa-components, and when graphene is chemically linked thereto, it is easy to regulate their corresponding band gap, which makes possible to fabricate a light emitting diode having a different wavelength.

### MODE FOR THE INVENTION

The present invention is further illustrated by the following examples. However, it shall be understood that these examples are only used to specifically set forth the present invention, rather than being understood that they are used to limit the present invention in any form.

### Example 1

A. Fabrication of zinc oxide-graphene quantum dots

To 40 ml of N,N-dimethylforamide, 40 mg of oxidized graphite was added and dispersed for 10 minutes by means of a homogenizer. On the other hand, 0.93 g of zinc acetate dehydrate [Zn(COO)₂2H₂O] was added to 200 ml of N,N-dimethylforamide and subjected to stirring. After 10 minutes, the solution in which the oxidized graphite was dispersed was mixed with the solution of zinc acetate dehydrate [Zn(COO)₂2H₂O], and then the resulting solution was stirred at 95° C., 150 rpm for 5 hours. The initial color of the solution was black, but it turned transparent after 30 minutes. After 1 hour, the solution was changed into hazy, followed by gradually turning to a white solution. After 5 hours, gray powders were generated within the transparent solution. These powders were washed with ethanol and then with distilled water, and moderately dried in a 55° C. oven. As a result, zinc oxide-graphene core-shell shaped quantum dot were synthesized.

FIG. 1 is a schematic diagram of synthesizing the zinc oxide-graphene core-shell type quantum dots obtained above.

### Test Example 1

The zinc oxide-graphene quantum dots obtained above were synthesized as core-shell shaped nanoparticles. In order to examine the structure of the zinc oxide-graphene quantum dots, the quantum dot nanoparticles and an X-ray diffraction pattern thereof were analyzed by using a transmission electron microscope (TEM). As shown in FIG. 2a, the zinc oxide-graphene core-shell shaped quantum dots had an average diameter of about 10 nm. Further, as shown in FIG. 2b of the X-ray diffraction pattern, in the case of the formed ZnO core, crystal faces of (100), (002) and (101) were observed, suggesting it is a polycrystalline ZnO nanoparticle. In the case of graphene, peaks of (002) and (100) with significantly higher full width at half maximum (HWHM) were observed, which demonstrates that the ZnO nanoparticle was covered with the single layer of graphene.

FIG. 3 is a photoluminescence spectrum of the zinc oxide-graphene core-shell shaped quantum dots prepared above. A Ti:Sapphire laser (wavelength: 365 nm) was used as an excitation light source, and peaks were observed at 379 nm (3.29 eV), 406 nm (3.05 eV), and 432 nm (2.86 eV), respectively. The peak at 379 nm was a light emitting representing transition between a conduction band (CB) and a valence band (VB) of ZnO. On the other hand, in the case of graphene covering the ZnO quantum dot core, the graphene in a semimetal state without any band gap due to the loading of 0.8% strain was changed into a semiconductor with the band gap of 190 meV which corresponded to the energy range of midinfrared. In the case of graphene, the Fermi energy was 4.4 eV. When such graphene changed into graphene with a band gap of 190 meV, the band gap was separated into a conduction band (CB) of 4.305 eV and a valence band (VB) of 4.495 eV. Generally, it has been known that in the case of ZnO, its energy levels of the conduction band (CB) and valence band (VB) were 4.19 eV and 7.39 eV, respectively. Therefore, the peaks at 406 nm (3.05 eV) and 432 nm (2.86 eV) represented the difference in energy (that is, 2.985 eV and 2.895 eV) generated from the transport of electrons from the conduction band (CB) of ZnO to the conduction band (CB) and valence band (VB) of graphene, followed by transition to the valence band (VB) of ZnO.

### Example 2

B. Fabrication of Zinc Oxide-Graphene Quantum Dot Light Emitting Diode

In order to form an electrode on a glass substrate, an ITO (Indium Tin Oxide) thin film was deposited on the glass substrate, followed by forming an ITO electron pattern through an etching process. After that, the glass substrate was coated with poly(3,4-ethylenedioxythiophene)poly(styrenesulfonate) (PED OT:PSS) by using a spincoater at a rate of 4000 rpm for 40 seconds, to thereby obtain a first conductive polymer layer. At this time, because the conductive polymer was hydrophilic, it was coated with a 0.5 μm hydrophilic filter so as to be uniformly deposited. After the coating, the glass substrate was dried at 110° C. for 10 minutes.

After the first conductive polymer (PEDOT) layer was formed, the glass substrate was coated with poly-(retra-N-phenylbenzidine)(Poly-TPD) by using a spincoater at a rate of 4000 rpm for 40 seconds, to thereby form a second conductive polymer layer. Here, because Poly-TPD was hydrophobic, it was uniformly sprayed on to the substrate by using a 0.2 μm hydrophobic filter. After that, the glass substrate was dried at 110° C. for about 30 minutes.

Next, the thus prepared zinc oxide-graphene quantum dot powder (10 ml) was dissolved in ethanol at a proper ratio and washed by using an ultrasonic cleaner for 10 minutes. The thus prepared zinc oxide-graphene quantum dot solution was deposited on the hardened second conductive polymer (poly-TPD) layer through spin coating by using a spincoater at a rate of 2000-4000 rpm for about 20-40 seconds. The substrate was subjected to soft baking at 90° C. for about 10-30 minutes. After the coating of the zinc oxide-graphene quantum dots, cesium carbonate (CsCO₃) powders (50 mg) were dispersed in 10 ml of 2-ethoxyethanol, to thereby prepared a cesium carbonate solution. The cesium carbonate solution was then deposited on the zinc oxide-graphene quantum dot layer through spin coating at a rate of 5000 rpm for about 30 seconds, followed by soft baking at 90° C. for about 10-30 minutes. Next, an Al electrode was deposited on each of the first conductive polymer (PEDOT:PSS) layer, second conductive polymer (poly-TPD) layer, zinc oxide-graphene quantum dot layer, and supplementary layer (cesium carbonate layer) by using a thermal evaporator in a thickness of 150 nm, to thereby fabricate a light emitting diode.

FIG. 4 is a schematic diagram of the polymer hybrid light emitting diode fabricated in a single active layer, comprising the zinc oxide-graphene quantum dots.

### Test Example 2

ITO was an anode electrode, and the first conductive polymer layer (PEDOT:PSS) was used as a hole injection layer which promotes the introduction of holes into the organic layer. FIG. 5 is a schematic energy band diagram of the light emitting diode. In the above light emitting diode, the second conductive polymer (Poly-TPD) layer was used as a hole transport layer, and the zinc oxide-graphene nanoparticle received electrons introduced from Al (cathode) and holes transported from the second conductive polymer (Poly-TPD) layer via a hopping mechanism. As a result, the diode showed light emitting properties by re-combining the electrons and holes in the zinc oxide-graphene quantum dots. FIG. 6 shows electrical properties of the light emitting diode. As shown in FIG. 6, the voltage for light emitting was approximately 10 V, and when 15 V of the voltage was applied, 200 mA/cm² of current density was observed.

In order to examine photoluminescence properties of the light emitting diode, electroluminescence (EL) was measured. FIG. 7 shows the measured photoluminescence properties. As shown in FIG. 7, there were observed four field emissive peaks at 428 nm (2.89 eV), 450 nm (2.74 eV), 490 nm (2.52 eV) and 606 nm(2.04 eV). When the electrons transferred from Cs₂CO₃/Al were introduced into the graphene, the Fermi energy level of the graphene has increased. Upon applying voltages (V), the concentration of electrons (n) was represented by n=aV, and the difference in Fermi level caused thereby was represented by ΔE_{F}=hv_{F}(p|n|)^{1/2}. Here, v_{F} was Fermi speed (0.8×10⁶m/s) of 7×10¹⁰cm²V¹, and when the applied voltage was 11-15 V, ΔE_{F} was in the range of 82-95 meV. At this time, the level of conduction band (CB) and valence band (VB) of ZnO was increased as much as the increased Fermi energy level due to ZnO materials and band correspondence. Finally, the light emitting energy of electron transition from the conduction band (CB) and valence band (VB) of the graphene to the increased valence band (VB) of ZnO was decreased as much as the increased Fermi energy, and thereby, in the PL spectrum, the electroluminescence at 406 nm and 432 nm was subjected to red shift to 428 nm and 450 nm, respectively. Electroluminescence lights at 428 nm and 450 nm were absorbed to poly-TPD and PSS:PEDOT, respectively, and filed emission corresponding to the energy between LUMO (lowest unoccupied molecular orbital) and HOMO (highly occupied molecular orbital) was occurred. Electroluminescence peaks at 490 nm and 606 nm were due to such field emission. FIG. 7 is an electroluminescence graph of the polymer hybrid light emitting diode comprising the zinc oxide-graphene quantum dots when +15 V of voltage was applied thereto. Further, FIG. 8 is schematic diagrams of PL and EL properties.

Meanwhile, color indices of emission (CIE) were (0.23, 0.20), (0.28, 0.24) and (0.31, 0.26) in forward orientation upon applying 13, 15 and 17 V of voltage, respectively, brightness was about 800 cd/m² (at 15V), and almost white light was observed with naked eyes.

Therefore, it has been found that when the voltage was applied, the light emitting diode using the metal oxide semiconductor-graphene core-shell quantum dots can induce filed emission to the difference in energy level between the conduction band (CB) and valence band (VB) of graphene and the valence band (VB) of the metal oxide semiconductor linked thereto. Based on this principle, red, green and blue electroluminescences useful for the fabrication of a white light emitting diode were expected as follows. FIG. 9 represents the relationship of a light emitting energy level to multi-component oxide semiconductor materials in which valence band energy levels of semiconductor nanoparticles, that are chemically linked to the graphene used in implementing red (610-630 nm (1.96-2.03 eV)), green (520-540 nm (2.29-2.38 eV)) and blue (440-460 nm (2.69-2.81 eV)) among electroluminescence, are in the range of 6.30-6.45 eV (red), 6.65-6.80 eV (green), and 7.00 7.25 eV (blue), respectively.

Specific terms used in the present description are given only to describe specific embodiments and are not intended to limit the present invention. Singular forms used in the present description include plural forms unless they apparently represent opposite meanings. The meaning of “including” or “having” used in the present description is intended to embody specific properties, regions, integers, steps, operations, elements and/or components, but is not intended to exclude presence or addition of other properties, regions, integers, steps, operations, elements, components and/or groups.

1. A metal oxide semiconductor-graphene core-shell quantum dot having a structure, wherein a metal oxide semiconductor nanoparticle is a core and said core is covered with graphene in a shell shape.

2. The metal oxide semiconductor-graphene core-shell quantum dot according to claim 1, wherein the metal oxide semiconductor is zinc oxide.

3. The metal oxide semiconductor-graphene core-shell quantum dot according to claim 1, wherein the graphene is composed of a graphene sheet which is in a single layer or a multi-layer.

4. The metal oxide semiconductor-graphene core-shell quantum dot according to claim 1, wherein the graphene is graphene having a band gap in a curved shape.

5. The metal oxide semiconductor-graphene core-shell quantum dot according to claim 1, wherein the metal oxide semiconductor nanoparticle forming a core is chemically linked to the graphene forming a shell through the chemical binding; to oxygen atoms.

6. The metal oxide semiconductor-graphene core-shell quantum dot according to claim 1, wherein the metal oxide semiconductor-graphene has electroluminescence, of an active layer generated in the visible ray region,

7. The metal oxide semiconductor-graphene core-shell quantum dot according to claim 1, wherein the metal oxide semiconductor-graphene is to mix red, green and blue light emitting semiconductor nanoparticles.

8. The metal oxide semiconductor-graphene core-shell quantum dot according to claim 1, wherein the metal oxide semiconductor-graphene has a conduction band (CB) energy level higher than the Fermi energy (4.4 eV) of graphene.

9. The metal oxide semiconductor-graphene core-shell quantum dot according to claim 1, wherein the metal oxide semiconductor-graphene is a multi-component metal oxide semiconductor having a valence band (VB) energy level composed of 6.30-6.45 eV (red), 6.65-6.80 eV (green) and 7.00 7.25 eV (blue) ranges.

10. The metal oxide semiconductor-graphene core-shell quantum dot according to claim 1, wherein the quantum dot has a size in 5˜30 nm.

11. A light emitting diode comprising the metal oxide semiconductor-graphene core-shell quantum dot according to claim 1 as a single active layer, which is a white light emitting diode.

12. A method of fabricating a light emitting diode, comprising:
preparing a solution by adding the metal oxide semiconductor-graphene quantum dot according to claim 1 to alcohol;
forming a first conductive polymer layer by coating a hydrophilic polymer on a transparent electrode substrate;
forming a second conductive polymer layer by coating a hydrophobic polymer on the first conductive polymer layer;
forming a single active layer by coating the alcohol solution of the metal oxide semiconductor-graphene quantum dot on the second conductive polymer layer;
forming a supplementary layer on the single active layer; and
forming a metal electrode layer.
